(19) United States
(12) Patent Application Publication
(10) Pub. No.: US 2009/0009959 A1
(43) Pub. Date: Jan. 8, 2009

(54) WATERPROOFING STRUCTURE FOR MICROCOMPUTER

(76) Inventor: Ta-Yang Cheng, Taipei (TW)

Correspondence Address: SCHMEISER, OLSEN & WATTS, 22 CENTURY HILL DRIVE, SUITE 302, LATHAM, NY, 12110, US

(21) Appl. No.: 11/773,457

(22) Filed: Jul. 5, 2007

(51) Int. Cl. H05K 7/20; G06F 1/16; H05K 5/00; H05K 7/00

(52) U.S. Cl. 361/687; 361/683

(57) ABSTRACT

A waterproofing structure for microcomputer includes a computer case being formed on outer surfaces with radiating fins, and having at least one end panel, on which a plurality of through holes are formed; a motherboard mounted in the computer case and having a CPU, electronic elements, and a storage unit mounted thereon, the motherboard also having a plurality of keys and connectors provided thereon corresponding to the through holes formed on the end panel of the computer case; and a plurality of waterproofing units separately fixedly mounted to the through holes on the end panel of the computer case for enclosing the plurality of keys and connectors therein, and each of the waterproofing units having an end fixedly located at an outer side of the panel with a cap removably mounted thereto. Therefore, the microcomputer is waterproof and usable on ship or under water, and has good heat radiating effect.

### FIELD OF THE INVENTION

The present invention relates to a waterproofing structure for microcomputer, and more particularly, to a waterproofing structure that not only makes a microcomputer usable on ship or under water, but also gives the microcomputer good heat radiating effect.

### BACKGROUND OF THE INVENTION

A conventional microcomputer generally has a heat radiating element arranged on a central processing unit (CPU) mounted on a motherboard of the microcomputer. The heat radiating element is attached to the CPU and has a fan assembled thereto. The heat radiating element absorbs heat generated by the CPU during operation thereof, so that heat is distributed over an expanded area. Then, the heat absorbed by the heat radiating element is blown away by airflows produced by the fan to dissipate in different directions.

However, since the motherboard of the microcomputer is mounted in a computer case that defines a closed space therein, and heat generated by the CPU as well as other electronic elements on the motherboard during operation thereof is circulated in the closed space of the computer case instead of being completely discharged from the computer case. Therefore, when the fan blows airflows toward the heat radiating element, hot airflows are formed to circulate in the closed computer case without creating good heat radiating effect. As a result, the CPU tends to have reduced operating efficiency or even becomes down due to overheat. Therefore, the conventional heat radiating element can not be used on a computer with a relatively high operating power.

Moreover, all the currently available microcomputers are not waterproof and would be burned out when the computer case thereof is invaded by water, and are therefore not usable on ship or under water. That is, the currently available microcomputers have limited applicability and fail to meet consumers' need in practical application thereof in terms of waterproofing and heat radiating.

### SUMMARY OF THE INVENTION

A primary object of the present invention is to provide a waterproofing structure for microcomputer, so that keys and connectors on the microcomputer are protected against water to be usable on ship or under water.

Another object of the present invention is to provide a waterproofing structure for microcomputer, so that the microcomputer is waterproof and has good heat radiating effect.

To achieve the above and other objects, the waterproofing structure for microcomputer according to the present invention includes a computer case being formed on outer surfaces with a plurality of radiating fins, and having at least one end panel, on which a plurality of through holes are formed; a motherboard mounted in the computer case and having a CPU, a plurality of electronic elements, and a storage unit mounted thereon, the motherboard also having a plurality of keys and connectors provided thereon corresponding to the through holes formed on the end panel of the computer case; and a plurality of waterproofing units separately fixedly mounted to the through holes on the end panel of the computer case for enclosing the plurality of keys and connectors therein, and each of the waterproofing units having an end fixedly located at an outer side of the panel with a cap removably mounted thereto.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a waterproofing structure for microcomputer according to a first embodiment of the present invention;

FIG. 2 is an assembled view of FIG. 1;

FIG. 3 is an enlarged view of the circled area A of FIG. 2;

FIG. 4 is a fragmentary sectioned side view of FIG. 4;

FIG. 5 is an exploded perspective view of a waterproofing structure for microcomputer according to a second embodiment of the present invention; and

FIG. 6 is an assembled view of FIG. 5.

### DETAILED DESCRIPTION OF THE PREFERRED EMBODIMENTS

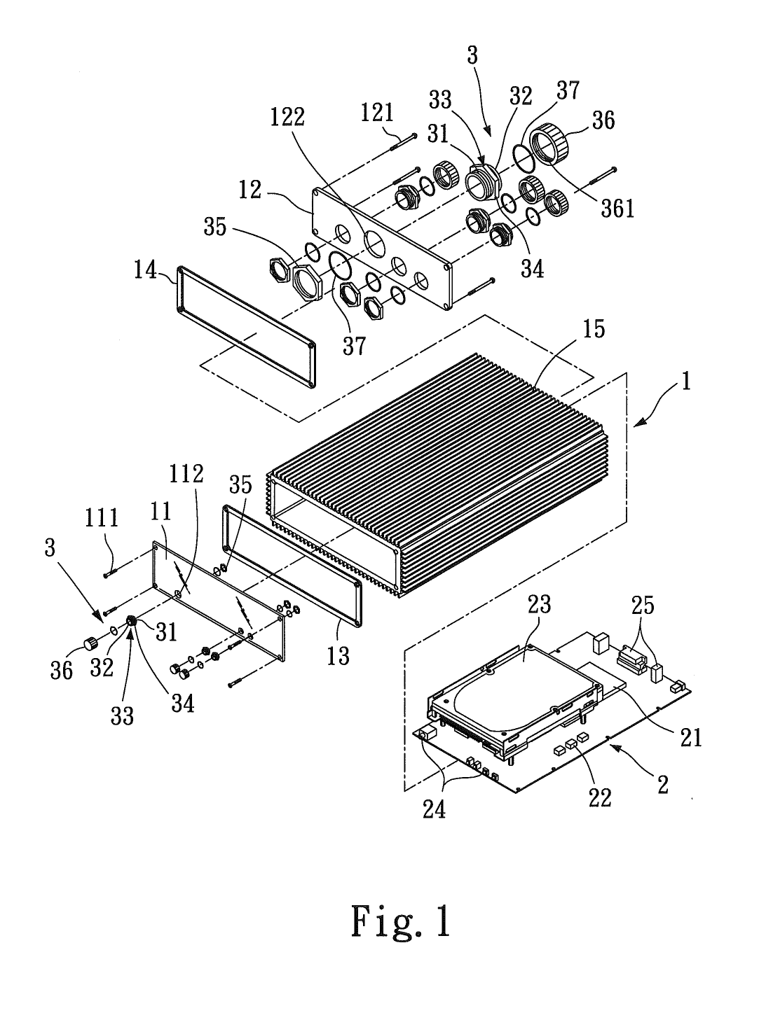

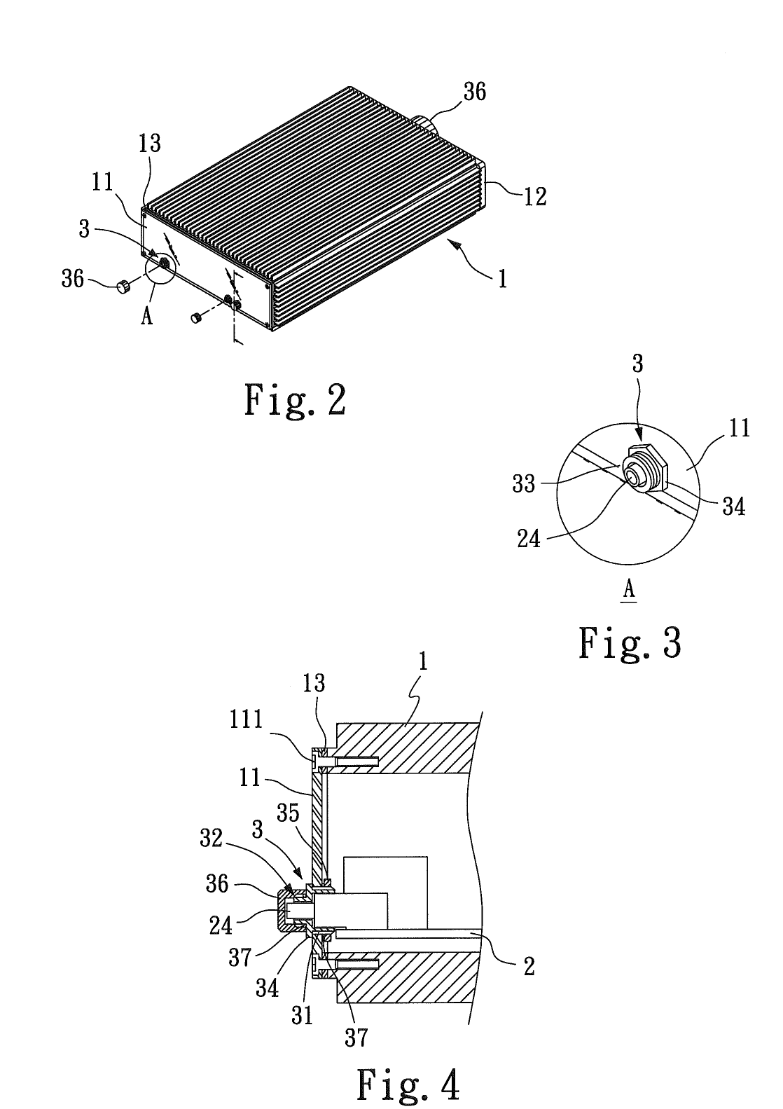

Please refer to FIGS. 1 and 2 that are exploded and assembled perspective views, respectively, of a waterproofing structure for microcomputer according to a first embodiment of the present invention, to FIG. 3 that is an enlarged view of the circled area A of FIG. 2, and to FIG. 4 that is a fragmentary sectioned side view of FIG. 2. As shown, the waterproofing structure for microcomputer according to the first embodiment of the present invention includes a computer case 1, a motherboard 2, and a plurality of waterproofing units 3. A microcomputer with the waterproofing structure of the present invention is watertight and usable on ship or under water, and has improved heat radiating ability.

The computer case 1 is provided at two opposite ends with a front panel 11 and a rear panel 12, which are fixed to the computer case 1 using fastening elements 111, 121. The front and the rear panel 11, 12 are provided at predetermined positions with a plurality of through holes 112, 122, respectively. Waterproof gaskets 13 and 14 are mounted between the front panel 11 and the computer case 1, and between the rear panel 12 and the computer case, respectively. Moreover, the computer case 1 is formed on outer surfaces with a plurality of radiating fins 15.

The motherboard 2 is mounted in the computer case 1, and has different components mounted thereon, including a central processing unit (CPU) 21, a plurality of electronic elements 22, and a storage unit 23. A plurality of keys 24 and connectors 25 are provided at two opposite ends of the motherboard 2 corresponding to the through holes 112 and 122 formed on the front and the rear panel 11, 12, respectively.

Each of the waterproofing units 3 includes at least a sleeve 33 having a first and a second externally threaded end 31, 32 axially extended in two opposite directions, and a stop flange 34 radially outward extended between the two externally threaded ends 31, 32. The sleeve 33 is fixedly mounted on the front or the rear panel 11, 12 in a corresponding through hole 112, 122 by extending the first externally threaded end 31 through the hole 112 or 122 into the computer case 1 to engage with a fastening element 35, which may be an internally threaded nut, so that a corresponding key 24 or connector 25 is enclosed in the sleeve 33. Meanwhile, the stop flange 34 on the sleeve 33 is pressed against an outer surface of the front or the rear panel 11, 12, allowing the second externally threaded end 32 to fixedly project from the front or the rear panel 11, 12 by a predetermined length for removably engaging with a corresponding cap 36 having an internally threaded surface 361. A waterproof gasket 37 is provided between each fastening element 35 and the first externally threaded end 31, and between each cap 36 and the second externally threaded end 32.

When a microcomputer with the above-described waterproofing structure according to the present invention is used on ship, all the required external apparatus and other necessary instruments on the ship may be separately plugged in the connectors 25 enclosed in the sleeves 33 of the waterproofing units 3 to thereby electrically connect to the motherboard 2, and the keys 24 enclosed in the sleeves 33 may be pushed to activate the electronic components 21, 22, 23 mounted on the motherboard 2 or to proceed with other operations on the microcomputer. The keys 24 and connectors 25 that have been pushed or connected to complete necessary operations or are not in use may be covered with the caps 36 by meshing the internally threaded surfaces 361 of the caps 36 with the externally threaded second ends 32 of the sleeves 33. With the waterproof gaskets 13, 14 mounted on the computer case 1, and the waterproof gaskets 37 mounted between the sleeves 33 and the fastening elements 35 and the caps 36, the microcomputer is effectively protected against invasion by water and can be safely used on ship or under water.

When the microcomputer with the waterproofing structure of the present invention is used under water, heat produced by the CPU 21 and other electronic elements 22 on the motherboard 2 during operation thereof is directly absorbed by the computer case 1 and transmitted to the radiating fins 15 on the outer surfaces of the computer case 1. And, heat absorbed by the radiating fins 15 is transferred to the water to achieve excellent heat dissipation effect for the microcomputer.

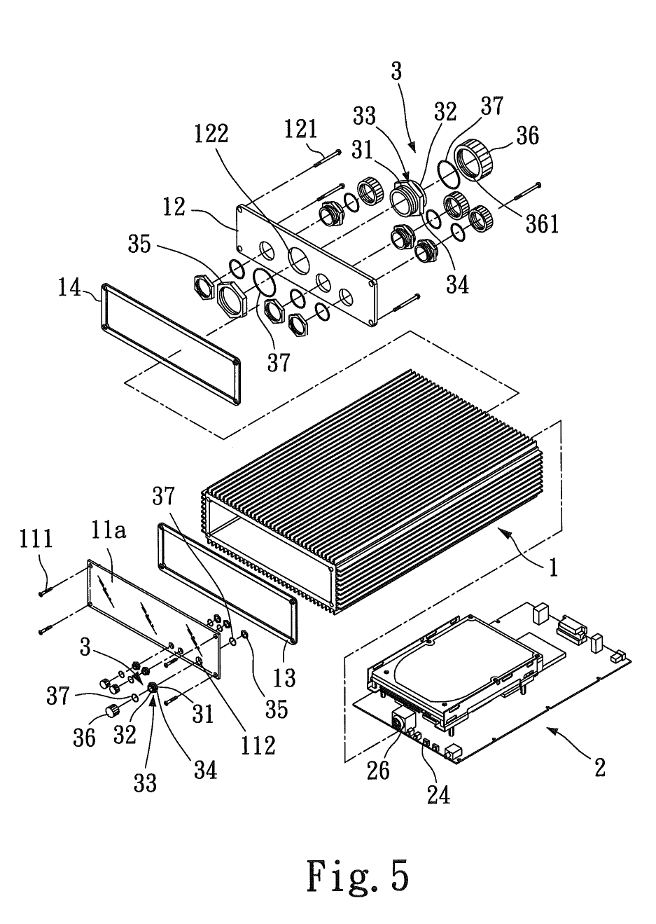

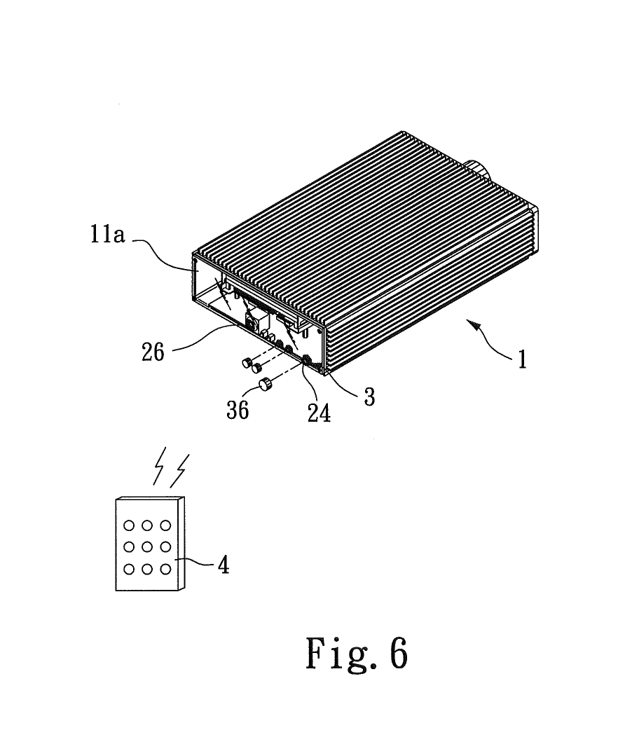

FIGS. 5 and 6 are exploded and assembled perspective views, respectively, of a waterproofing structure for microcomputer according to a second embodiment of the present invention. The second embodiment is generally structurally similar to the first embodiment, except for a front panel 11a made of a transparent material and a receiving unit 26 provided at one end of the motherboard 2 in the vicinity of the plurality of keys 24 for receiving related signals from a corresponding remote controller 4, so that the electronic components 21, 22, 23 on the motherboard 2 may be remotely controlled to operate.

With the above arrangements, the waterproofing structure for microcomputer according to the present invention effectively eliminates the drawbacks in the conventional microcomputers to not only protect the keys and connectors on the microcomputers against water and thereby allow the microcomputers to be used on ship or under water, but also give the microcomputers improved heat radiating effect, making the microcomputers more practical for use.

What is claimed is:

1. A waterproofing structure for microcomputer, comprising:
a computer case being provided on at least a first end with a panel, on which a plurality of through holes are formed;
a motherboard being mounted in the computer case and having a central processing unit (CPU), a plurality of electronic elements, and a storage unit mounted thereon; the motherboard also having a plurality of keys and connectors provided thereon corresponding to the plurality of through holes formed on the panel of the computer case; and
a plurality of waterproofing units being separately fixedly mounted to the through holes on the panel of the computer case for enclosing the plurality of keys and connectors therein; and each of the waterproofing units having an end fixedly located at an outer side of the panel with a cap removably mounted thereto.

2. The waterproofing structure for microcomputer as claimed in claim 1, wherein the computer case is formed on outer surfaces with a plurality of radiating fins.

3. The waterproofing structure for microcomputer as claimed in claim 1, further comprising a waterproof gasket mounted between the computer case and the panel.

4. The waterproofing structure for microcomputer as claimed in claim 1, further comprising another panel mounted to a second end of the computer case opposite to the first end.

5. The waterproofing structure for microcomputer as claimed in claim 1, wherein the panel is made of a transparent material.

6. The waterproofing structure for microcomputer as claimed in claim 1, wherein the motherboard is provided at one end in the vicinity of the plurality of keys with a receiving unit.

7. The waterproofing structure for microcomputer as claimed in claim 1, wherein each of the waterproofing units includes a sleeve having a first and a second externally threaded end axially extended in two opposite directions, and a stop flange radially outward extended between the first and the second externally threaded end; and the first externally threaded end of the sleeve being fixedly located in a corresponding one of the plurality of throughholes on the panel of the computer case to engage with a fastening element, such that the second externally threaded end of the sleeve is outward extended from the panel to removably engage with the cap.

8. The waterproofing structure for microcomputer as claimed in claim 1, wherein the cap is provided on an internal surface with screw threads.

9. The waterproofing structure for microcomputer as claimed in claim 7, further comprising a waterproof gasket mounted between the first externally threaded end of the sleeve and each fastening element, and between the second externally threaded end of the sleeve and each cap.

10. The waterproofing structure for microcomputer as claimed in claim 7, wherein the fastening element is an internally threaded nut.
